(19) United States
(12) Patent Application Publication
(10) Pub. No.: US 2019/0302143 A1
(43) Pub. Date: Oct. 3, 2019

(54) ATTACHMENT DEVICE FOR MONITORING POWER SYSTEMS

(71) Applicant: Vollspark Ltd., Tel Aviv (IL)

(72) Inventor: Liran Katzir, Tel Aviv (IL)

(21) Appl. No.: 16/362,655

(22) Filed: Mar. 24, 2019

(30) Foreign Application Priority Data
Mar. 29, 2018 (GB) GB1805154.0

(51) Int. Cl. G01R 1/04; G01R 31/02; F16B 1/00

(52) U.S. Cl. CPC G01R 1/04; H02J 7/0068; F16B 1/00; G01R 31/027

(57) ABSTRACT

A monitoring devices and electrically insulated elongated member for installing a monitoring device on a utility asset while maintaining a safe approach distance during operation of the power equipment. The monitoring device includes: a housing having a receptacle member adapted for detachably mating with a distal end of the electrically insulated elongated member and a permanent magnet mounted on the housing. The magnet magnetically attaches the device to the power equipment.

### BACKGROUND

### 1. Technical Field

The present invention relates to monitoring of equipment in the electrical power distribution grid.

### 2. Description of Related Art

North America's electricity infrastructure represents more than $1 trillion U.S. dollars (USD) in asset value and includes over 360,000 miles of transmission lines, including approximately 180,000 miles of high-voltage lines, connecting over 6,000 power plants. Power and distribution transformers are a critical component of the electrical power grid, because power and distribution transformers adjust the electric voltage to a suitable level on each segment of the power transmission from generation to the end user. Power and distribution transformers step up voltage at generation for efficient, long-haul transmission of electricity and step voltage down for local distribution to customers.

Traditionally, utility assets such as power transformers have been maintained and replaced according to a previously determined maintenance schedule. Maintenance is normally performed by de-energizing a portion of the electrical grid, performing the scheduled maintenance task and reenergizing the grid.

There is worldwide trend toward implementing real time monitoring infrastructure and using real time information to maintain and replace utility assets. Real time information with respect to various parameters of the power grid may include temperature of an asset, the amount of current flowing through an asset and/or many other measurable parameters. The use of real-time information is expected to improve overall efficiency of the power grid and to decrease maintenance costs and reduce the number of failures and blackouts.

### BRIEF SUMMARY

Various monitoring devices and/or various electrically insulated elongated members are disclosed herein for installing the monitoring devices on a utility asset while maintaining a previously specified safe approach distance during operation of the power equipment. The monitoring devices include: a housing having a receptacle member adapted for detachably mating with a distal end of an electrically insulated elongated member and a permanent magnet mounted on the housing. The magnet is configured to magnetically attach the device to the power equipment. The receptacle member may include a slot and the distal end of the electrically insulated elongated member may include a protrusion configured to detachably mate with the slot. The receptacle member may include a threaded hole and the distal end of the electrically insulated elongated member may include a threaded rod configured to detachably mate with the threaded hole. The distal end of the electrically insulated elongated member may include opposing fingers and the receptacle member may include a contour in the housing of the monitoring device which is configured to detachably be held by the opposing fingers. The monitoring device may include an environmental sensor disposed internal to or on the housing. The monitoring device may include: a microprocessor, a communications transceiver for conveying a sensory datum from the environmental sensor, an energy storage component for powering the microprocessor and the communications transceiver; and an energy harvesting component for charging the energy storage component. The electrically insulated elongated member may include a proximal end configured to manipulate the monitoring device while maintaining a previously specified safe approach distance during operation of the power equipment. The length of the electrically insulated elongated member is at least the previously specified safe approach distance.

Various methods are disclosed herein for mounting a monitoring device on an external surface of high voltage power equipment while maintaining a previously specified safe approach distance during operation of the power equipment. The monitoring device includes a housing having a receptacle member and a permanent magnet mounted on an external surface of the housing. The methods include attaching a distal end of an electrically insulated elongated member to the receptacle member adapted thereto of the housing. By manipulating the device from the proximal end of the electrically insulated elongated member, the device is magnetically attached to the external surface of the power equipment using a permanent magnet mounted on an external surface of the housing. By further manipulating the device from the proximal end of the electrically insulated elongated member, the distal end of the electrically insulated elongated member is detached from the receptacle member.

### BRIEF DESCRIPTION OF THE DRAWINGS

The invention is herein described, by way of example only, with reference to the accompanying drawings, wherein:

FIG. 1 illustrates a conventional distribution transformer;

FIG. 2 illustrates the conventional distribution transformer as shown in FIG. 1 with a monitoring device attached according to features of the present invention;

FIG. 3 illustrates attachment of the monitoring device using an elongated insulated member, according to features of the present invention;

FIG. 4A illustrates front view of an exemplary monitoring device, according to features of the present invention;

FIG. 4B illustrates rear view of an exemplary monitoring device, according to features of the present invention;

FIG. 4C illustrates side view of an exemplary monitoring device, according to features of the present invention;

FIG. 4D illustrates bottom view of an exemplary monitoring device, according to features of the present invention;

FIG. 5 illustrates an exemplary monitoring device and elongated insulated member used for attaching monitoring device on a utility asset, according to features of the present invention; and

FIG. 6 is a schematic block diagram of exemplary circuitry included in the monitoring device, according to features of the present invention;

FIG. 7 is a flow diagram illustrating a method, according to an embodiment of the present invention.

The foregoing and/or other aspects will become apparent from the following detailed description when considered in conjunction with the accompanying drawing figures.

### DETAILED DESCRIPTION

Reference will now be made in detail to features of the present invention, examples of which are illustrated in the accompanying drawings, wherein like reference numerals refer to like elements throughout. The features are described below to explain the present invention by referring to the figures.

By way of introduction, aspects of the present invention are directed to a method of attachment of a monitoring device on a utility asset, e.g. power/distribution transformer without necessarily de-energizing the utility asset and the electrical connections thereto, and while maintaining safe approach distances to the energized equipment. According to features of the present invention, a permanent magnet may be mounted on the underside of the monitoring device. Thus, with use of embodiments of the present invention, monitoring devices may be installed on utility assets safely and without the inconvenience of a temporary power outage.

An elongated insulated member may be used to manipulate the device toward the energized utility asset. The length of the elongated insulated member is at least a previously specified distance of safe approach to energized power equipment. The casing of the asset may be produced from a ferromagnetic material, e.g. galvanized steel. When the underside of the monitoring device approaches the ferromagnetic casing, the device magnetically attaches to the casing with the assistance of the magnetic force between the magnetic and the ferromagnetic casing. The device may include energy harvesting circuitry, sensors and a transceiver so that information, e.g. measured parameters, with respect to the utility asset may be conveyed, over a communications network, subsequent to the attachment of the monitoring device.

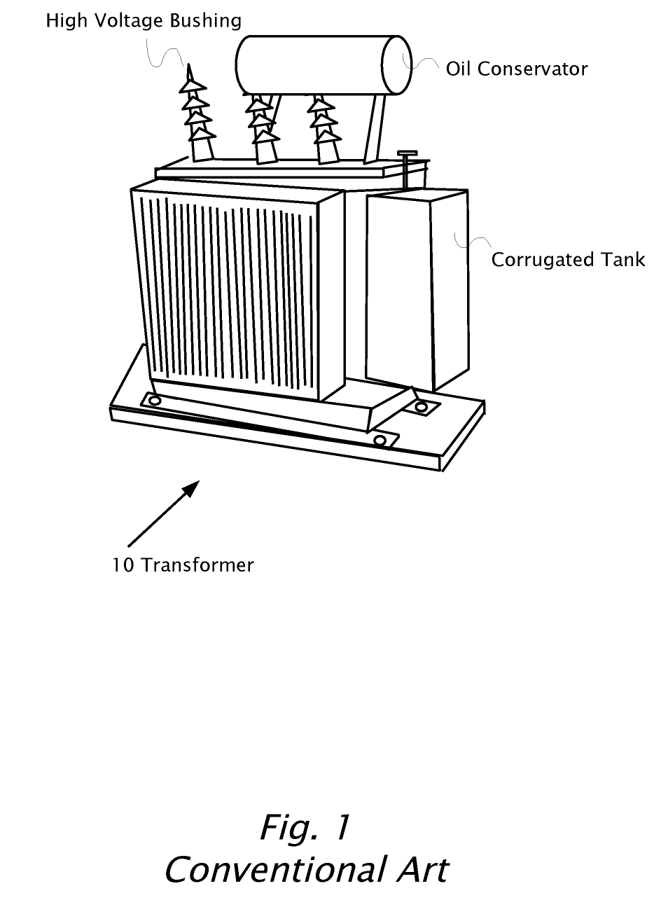

Referring now to the drawings, reference is now made to FIG. 1, which illustrates a conventional distribution transformer 10 as an example of a utility asset for which monitoring operational parameters is desired. Some of the parts of transformer 10 are labelled including: high voltage bushing, corrugated tank and oil conservator.

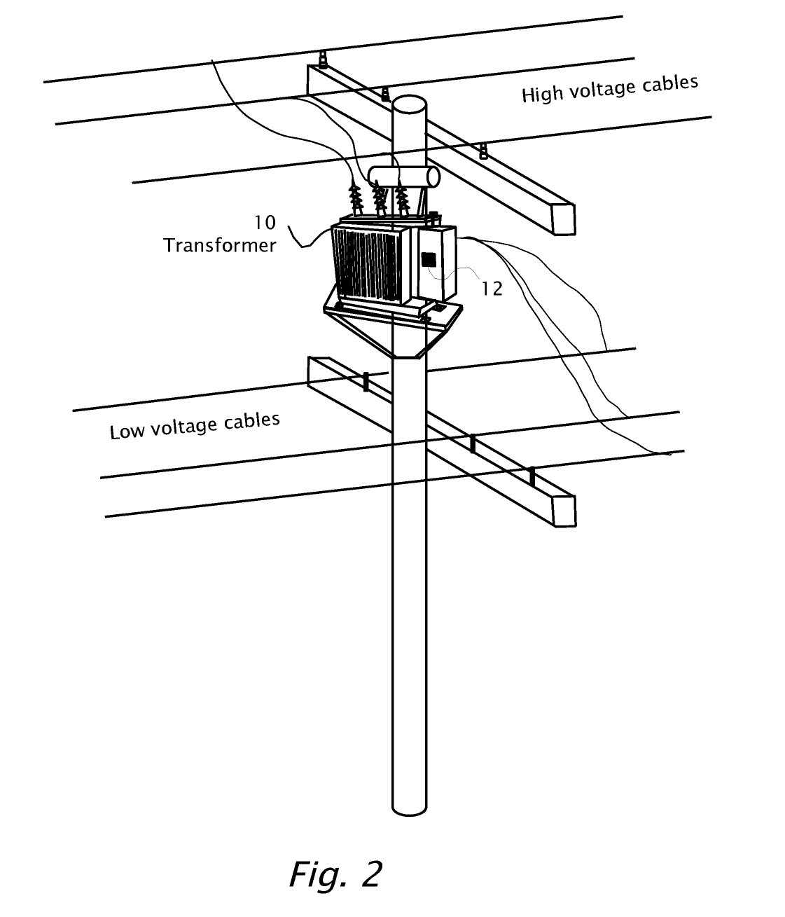

Reference is now also made to FIG. 2, which illustrates distribution transformer 10 as shown in FIG. 1, mounted on a pole with connections shown by way of example to high voltage and lower voltage power lines. A monitoring device 12 is shown attached to the surface of the corrugated tank, according to features of the present invention.

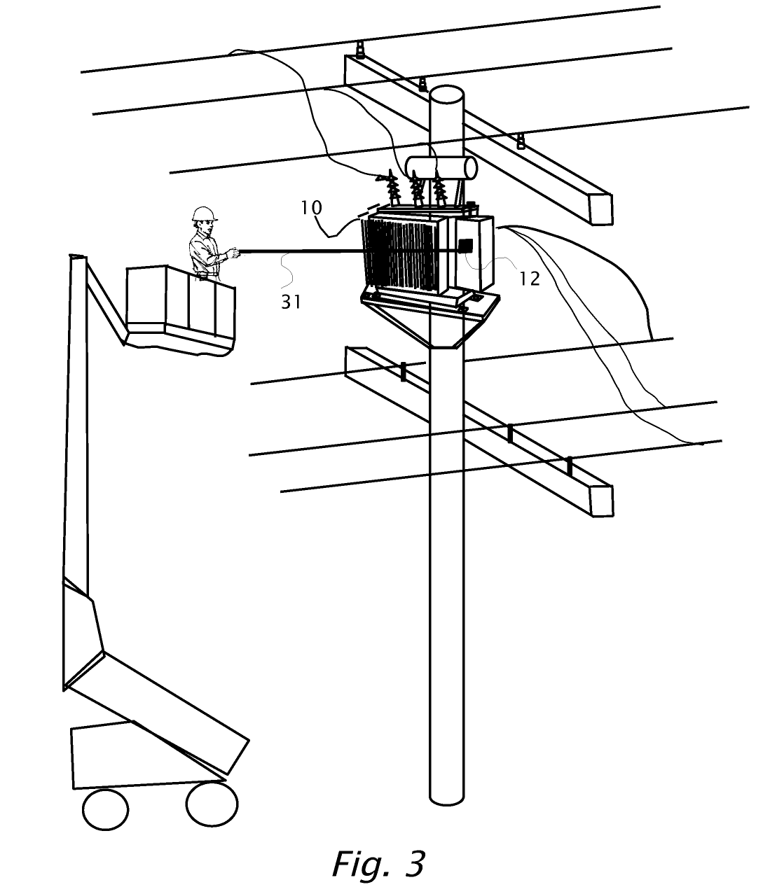

Reference is now also made to FIG. 3, which illustrates attachment of monitoring device 12 using an elongated insulated member 31, according to features of the present invention. By way of example, a qualified person is shown using elongated insulated member 31 to manipulate monitoring device 12 and attached monitoring device 12 to the corrugated tank of transformer 10. During the attachment process, transformer 10 may be operating. High voltage lines and low voltage lines may be carrying electrical power. Use of elongated insulated member 31, allows the qualified person to maintain safe distances of approach to all of the energized assets, including transformer 10 and the energized power lines. Elongated insulated member 31 may be produced from an electrically insulated material such as plastic, ceramic or wood thus does not conduct electricity sufficiently to cause a safety hazard or otherwise attract a discharge from the energized utility assets. Cross section of elongated insulated member 31, may be round, square, or otherwise polygonal with diameter or otherwise lateral dimension generally between 2-20 centimeters and determined by mechanical design so that elongated insulated member 31 does not measurably bend under load during use. Elongated insulated member 31 may be hollow with wall thickness nominally between 2-5 millimeters. Elongated insulated member 31 may be telescopic with multiple segments that at least partially fit into each other end to end.

Alternative methods for attachment of monitoring device 12 using an elongated insulated member 31 may include use of a robotic arm which may be operated under human control, semi-automatically under human control or fully automatically using machine vision techniques.

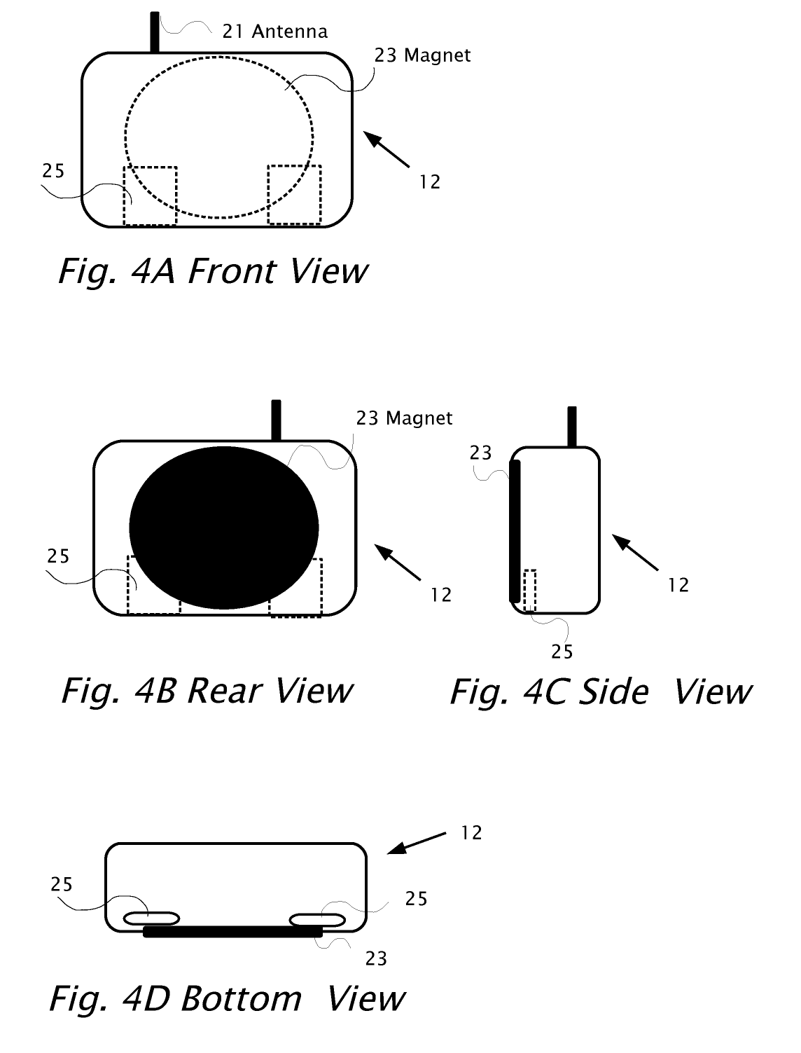

Reference is now also made to FIGS. 4A-4D which illustrate respectively front, rear, side and bottom views of an exemplary monitoring device 12, according to features of the present invention. The housing of device 12 may be produced from a ferromagnetic material or non-ferromagnetic material such as aluminium. Mounted on the underside of device 12 may be a permanent magnet 23. Alternatively, multiple permanent magnets may be used. The shape, number and/or configuration of magnets 23 may vary. An external antenna 21 is shown to facilitate wireless communications with device 12. One or more receptacles, e,g. slots 25 in housing of device 12 are configured to receive a distal portion of elongated insulated tool 31.

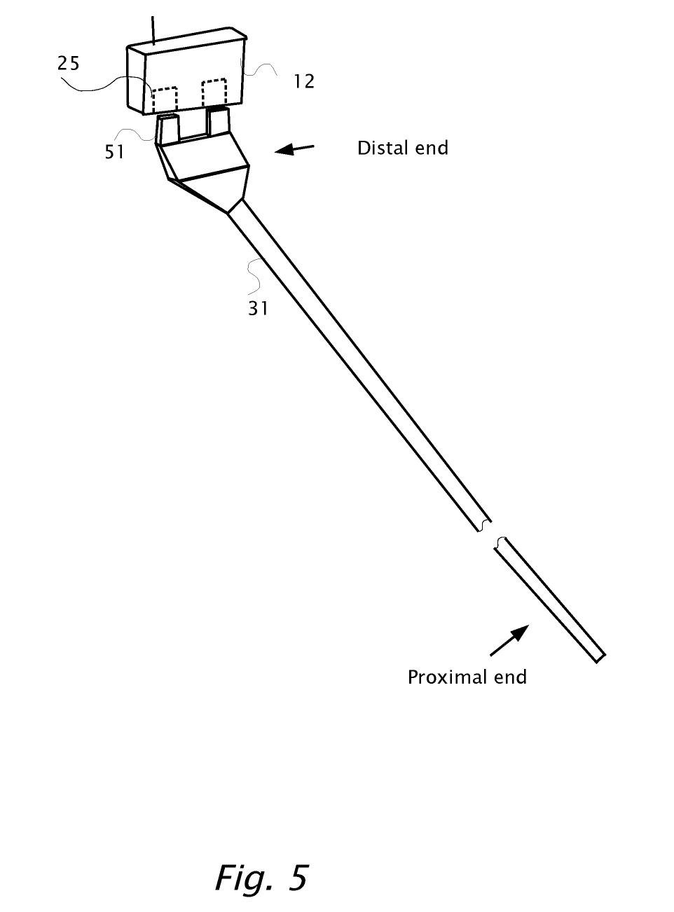

Reference is now also made to FIG. 5, which illustrates monitoring device 12 and elongated insulated member 31 used for attaching monitoring device on a utility asset, according to features of the present invention. By way of example, the distal portion of elongated insulated tool 31 includes one or more protrusions 51 adapted to detachably fit into slots 25 of device 12. Other receptacle members 25 and mating portions at the distal end of elongated insulated tool 31 may alternatively be used. Receptacle member 25 may be a threaded hole and the distal end of elongated insulated tool 31 may include a threaded rod for turning into the threaded hole. Alternatively, distal end of elongated insulated tool 31 may include opposing fingers which are configured to close around an outer contour of the housing of device 12.

Monitoring device 12 may include a lock and release mechanism so that when device 12 is in the air and held at the distal end of elongated insulated tool 31, device 12 is locked onto receptacle member 25 at the distal end of elongated insulated tool 31. When magnetic attachment is achieved, mechanical pressure may cause protrusions 51 to be released from receptacle member e.g. slots 25.

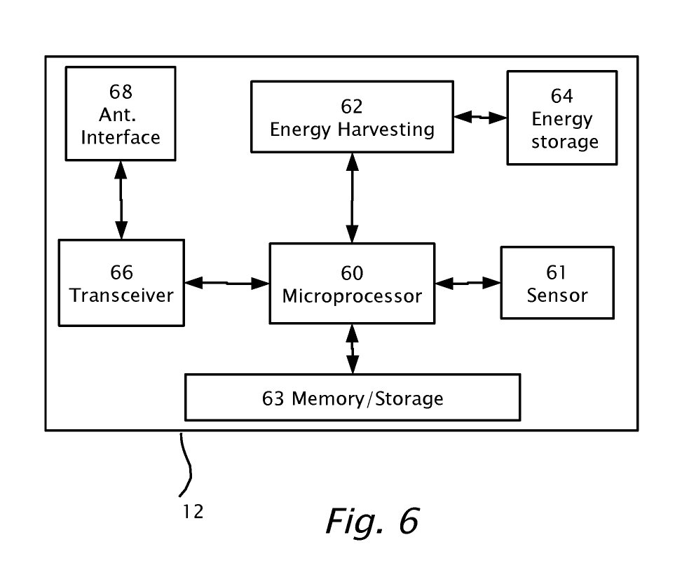

Reference is now made to FIG. 6, which includes a schematic block diagram, illustrating other features, according to the present invention, of monitoring device 12. Monitoring device may have a microprocessor 60 and/or other electronic control circuitry. Energy storage 64 such as a battery or capacitor supplies power to microprocessor 60. An energy harvesting mechanism 62 may include one or more of: a photo-voltaic system with a photo-voltaic panel mounted on the housing of device 12; a piezoelectric cantilever for generating electricity from transformer 10 tank vibrations; and harvesting energy from stray electromagnetic fields using an inductive and/or capacitive coupling. Sensors 61 may include devices for measuring temperature, vibration, acoustic, ultrasonic, humidity, location sensor using for instance global position system (GPS), accelerometer, gyroscope, electric field, magnetic field, et cetera. A communications transceiver 66, which may be a wireless cellular transceiver such as GSM (Global System for Mobile Communications), a power-line transceiver or other communications technology may be used to receive the monitoring information. The communications may be facilitated with an external antenna 21 (FIG. 4A) attachable to antenna interface 68. Measured sensory data may be logged in memory/storage 63.

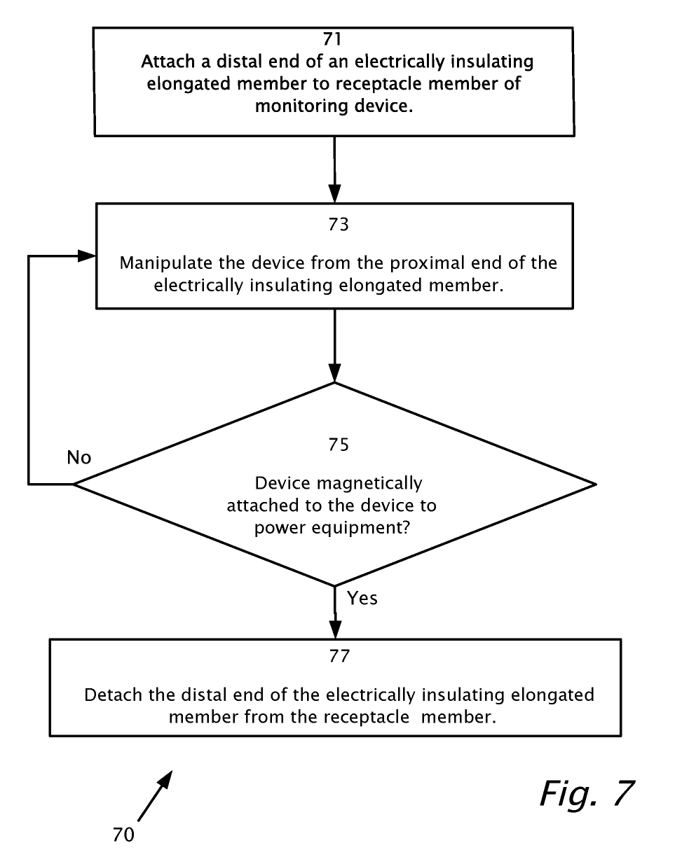

Reference is now made to FIG. 7 which illustrates a flowchart 70 of a method according to features of the present invention. The distal end of electrically insulated elongated member 31 is attached (step 71) to receptacle member 25 of monitoring device 12. Device 12 is thus manipulated (step 73) from the proximal end of the electrically insulated elongated member 31, while the qualified person is maintaining a safe distance of approach to the energized equipment, e.g power transformer 10. When monitoring device 12 is magnetically attached to an external surface of the power equipment, (decision block 75), then the distal end of electrically insulated elongated member 31 is detached (step 77) from receptacle member 25 of device 12.

The terms “power equipment” and “utility asset” are used herein interchangeably and refer to power transformers, distribution transformers, motors, generators, power lines and support structures thereof which operate or support high voltage (greater than 1000 Volts).

The term “proximal end” as used herein in the context of electrically insulated elongated member 31 refers to a handle used for a qualified person to handle the device using the electrically insulated elongated member 31.

The term “distal end” as used herein in the context of electrically insulated elongated member 31 refers to the far end of electrically insulated elongated member 31 which attaches to monitoring device 12.

The term “fingers” as used herein refers to mechanical fingers designed to operate similarly as fingers of the human hand with one or more joints per finger.

The term “safe approach distance” may be specified in national and/or state regulations dependent on the country and/or industry safety standards. The safe approach distance may vary dependent on the voltage, the type of utility asset and the level of training of the personnel. For example, United States 29 CFR 1910.333: Selection and Use of Work Practices, specifies safe approach distances between around 30 centimeters and 305 centimeters (10 feet) dependent on the voltage between 250 Volts and 50 kiloVolts under different circumstances. Canadian Occupational Health and Safety Regulation Part 19 specifies 6 meters as a minimum approach distance when working with electrical equipment up to 550 kiloVolt. The length of electrically insulated elongated member 31 may be nominally selected accordingly to be between 30 centimeters and greater than ˜6 meters.

The term “manipulate” as used herein may refer to manipulation by a person or by a mechanical arm or robot.

The term “plastic” in the context of an insulating material of which electrically insulated elongated member 31 may be produced may be selected from (but are not limited to) plastic materials (and combinations/copolymers thereof): polystyrene, polyvinyl chloride (PVC), polypropylene and polyethylene, Acrylonitrile butadiene styrene (ABS), Nylon 6, Nylon 6-6, Polyamides (PA), Polybutylene terephthalate (PBT), Polycarbonates (PC), Polyetheretherketone (PEEK), Polyetherketone (PEK), Polyethylene terephthalate (PET), Polyimides, Polyoxymethylene plastic (POM/Acetal), Polyphenylene sulfide (PPS), Polyphenylene oxide (PPO), Polysulphone (PSU) and Polytetrafluoroethylene (PTFE/Teflon

The transitional term “comprising” as used herein is synonymous with “including”, and is inclusive or open-ended and does not exclude additional, unrecited elements or method steps. The articles “a”, “an” is used herein, such as “a magnet” or “a sensor” have the meaning of “one or more” that is “one or more magnets”, “one or more sensors”.

All optional and preferred features and modifications of the described embodiments and dependent claims are usable in all aspects of the invention taught herein. Furthermore, the individual features of the dependent claims, as well as all optional and preferred features and modifications of the described embodiments are combinable and interchangeable with one another.

Although selected features of the present invention have been shown and described, it is to be understood the present invention is not limited to the described features.

1. A monitoring device for monitoring power equipment, the monitoring device comprising:
a housing including a receptacle member adapted for detachably mating with a distal end of an electrically insulated elongated member;
a permanent magnet mounted on the housing, wherein the magnet is configured to magnetically attach the device to the power equipment;
an environmental sensor disposed internal to or on the housing;
a microprocessor;
a communications transceiver for conveying a sensory datum from the environmental sensor;
an energy storage component for powering the microprocessor and the communications transceiver; and
an energy harvesting component for charging the energy storage component

2. The monitoring device of claim 1, wherein the receptacle member includes a slot and the distal end of the electrically insulated elongated member includes a protrusion configured to detachably mate with the slot.

3. The monitoring device of claim 1, wherein the receptacle member includes a threaded hole and the distal end of the electrically insulated elongated member includes a threaded rod configured to detachably mate with the threaded hole.

4. The monitoring device of claim 1, wherein distal end of the electrically insulated elongated member includes opposing fingers and the receptacle member includes a contour in the housing of the monitoring device which is configured to detachably be held by the opposing fingers.

5. The monitoring device of claim 1, wherein the electrically insulated elongated member includes a proximal end configured to manipulate the monitoring device while maintaining a previously specified safe approach distance during operation of the power equipment.

6. A monitoring kit, for monitoring power equipment, the monitoring kit comprising:
a monitoring device;
electrically insulated elongated member;
wherein the monitoring device includes:
a housing including a receptacle member adapted for detachably mating with a distal end of the electrically insulated elongated member; and
a permanent magnet mounted on the housing, wherein the magnet is configured to magnetically attach the device to the power equipment.

7. The monitoring kit of claim 6, wherein the receptacle member includes a slot and the distal end of the electrically insulated elongated member includes a protrusion configured to detachably mate with the slot.

8. The monitoring kit of claim 6, wherein the receptacle member includes a threaded hole and the distal end of the electrically insulated elongated member includes a threaded rod configured to detachably mate with the threaded hole.

9. The monitoring kit of claim 6, wherein distal end of the electrically insulated elongated member includes opposing fingers and the receptacle member includes a contour in the housing of the monitoring device which is configured to detachably be held by the opposing fingers.

10. The monitoring kit of claim 6, wherein the monitoring device includes:
an environmental sensor disposed internal to or on the housing.

11. The monitoring kit of claim 10, wherein the monitoring device includes:
a microprocessor;
a communications transceiver for conveying a sensory datum from the environmental sensor;
an energy storage component for powering the microprocessor and the communications transceiver; and
an energy harvesting component for charging the energy storage component.

12. The monitoring kit of claim 6, wherein the electrically insulated elongated member includes a proximal end configured to manipulate the monitoring device while maintaining a previously specified safe approach distance during operation of the power equipment.

13. An electrically insulated elongated member comprising:
a distal end configured for detachably mating a receptacle member constructed in a housing of a monitoring device for monitoring power equipment; and
a proximal end configured to manipulate the monitoring device and to magnetically attach the monitoring device to an external ferromagnetic surface of power equipment while maintaining a previously specified safe approach distance during operation of the power equipment.

14. The electrically insulated elongated member of claim 13, wherein the receptacle member includes a slot and the distal end of the electrically insulated elongated member includes a protrusion configured to detachably mate with the slot.

15. The electrically insulated elongated member of claim 13, wherein the receptacle member includes a threaded hole and the distal end of the electrically insulated elongated member includes a threaded rod configured to detachably mate with the threaded hole.

16. The electrically insulated elongated member of claim 13, wherein distal end of the electrically insulated elongated member includes opposing fingers and the receptacle member includes a contour in the housing of the monitoring device which is configured to detachably be held by the opposing fingers.

17. A method for mounting a monitoring device on an external surface of high voltage power equipment during operation of the power equipment, the monitoring device including a housing having a receptacle member and a permanent magnet mounted on an external surface of the housing, the method comprising:
attaching a distal end of an electrically insulated elongated member to the receptacle member adapted thereto of the housing;
by manipulating the device from the proximal end of the electrically insulated elongated member, magnetically attaching the device to the external surface of the power equipment using a permanent magnet mounted on an external surface of the housing; and
by further manipulating the device from the proximal end of the electrically insulated elongated member, detaching the distal end of the electrically insulated elongated member from the receptacle member.
